(19) United States
(12) Patent Application Publication
(10) Pub. No.: US 2024/0188410 A1
(43) Pub. Date: Jun. 6, 2024

(54) DISPLAY DEVICE

(71) Applicant: LG Display Co., Ltd., Seoul (KR)

(72) Inventors: Seung Han PAEK, Paju-si (KR); Yong In PARK, Paju-si (KR); Hyun Jin AN, Paju-si (KR); Kyung Jae YOON, Paju-si (KR); Jeon Phill HAN, Paju-si (KR); Yu Cheol YANG, Paju-si (KR)

(21) Appl. No.: 18/522,409

(22) Filed: Nov. 29, 2023

(30) Foreign Application Priority Data
Dec. 2, 2022 (KR) 10-2022-0166356
Sep. 5, 2023 (KR) 10-2023-0117816

(51) Int. Cl. H10K 77/10; H10K 59/65

(52) U.S. Cl. CPC H10K 77/10; H10K 59/65

(57) ABSTRACT

Embodiments disclose a display device including a glass substrate including a display area, a light-transmitting area, and a non-display area surrounding the light-transmitting area, a circuit portion and a light-emitting element portion disposed in the display area; and an etch stop pattern disposed in the non-display area, wherein the glass substrate includes a first opening disposed at a position corresponding to the light-transmitting area, the etch stop pattern includes a first etch stop layer surrounding the first opening and a second etch stop layer disposed on the first etch stop layer, and the second etch stop layer includes a protrusion extending further toward the light-transmitting area than the first etch stop layer.

### CROSS-REFERENCE TO RELATED APPLICATION

This application claims priority to and the benefit of Korean Patent Applications No. 10-2022-0166356, filed on Dec. 2, 2022, and No. 10-2023-0117816, filed on Sep. 5, 2023, the disclosure of which is incorporated herein by reference in its entirety.

### BACKGROUND

### Technical Field

Embodiments relate to a display device.

### Description of the Related Art

Electroluminescence display devices are classified into inorganic light-emitting display devices and organic light-emitting display devices depending on materials of an emission layer. An active-matrix-type organic light-emitting display device includes an organic light-emitting diode (OLED) that emits light by itself and has advantages of a quick response time, high luminous efficiency, high luminance, and a wide viewing angle. The organic light-emitting display device has OLEDs formed in each pixel. The organic light-emitting display device not only has a quick response time, high luminous efficiency, high luminance, and a wide viewing angle, but also represents a black grayscale as perfect black, and thus has an excellent contrast ratio and color gamut.

### BRIEF SUMMARY

Recently, organic light-emitting display devices have been implemented on a plastic substrate, which is a flexible material. The inventors of the present disclosure have appreciated that there are some benefits to have the display devices implemented on a glass substrate due to various issues. However, the inventors have also recognized that when the organic light-emitting display devices are implemented on the glass substrates, there is a technical problem that rigidity is reduced when processing notches or rounds or forming holes in a panel and it is difficult to process various shapes. Various embodiments of the present disclosure provide display devices addressing the various technical problems in the related art including the above-identified problem.

For example, embodiments provide a display device that maintains rigidity while processing a glass substrate and forming holes of various shapes.

Embodiments may allow the sharpness of an edge of a glass substrate to be mitigated.

It should be noted that the object of the present disclosure is not limited to the above-described object, and other objects of the present disclosure will be apparent to those skilled in the art from the following descriptions.

According to an aspect of the present disclosure, there is provided a display device including a glass substrate including a display area, a light-transmitting area, and a non-display area surrounding the light-transmitting area, a circuit portion and a light-emitting element portion disposed in the display area, and an etch stop pattern disposed in the non-display area, wherein the glass substrate includes a first opening disposed at a position corresponding to the light-transmitting area, the etch stop pattern includes a first etch stop layer surrounding the first opening and a second etch stop layer disposed on the first etch stop layer, and the second etch stop layer includes a protrusion extending further toward the light-transmitting area than the first etch stop layer.

According to another aspect of the present disclosure, there is provided a display device including a glass substrate including a display area, a light-transmitting area, and a non-display area surrounding the light-transmitting area, a circuit portion and a light-emitting element portion disposed in the display area, and an etch stop pattern disposed in the non-display area, wherein the glass substrate includes a first opening disposed at a position corresponding to the light-transmitting area, the glass substrate includes one surface on which the etch stop pattern is disposed and the other surface opposite to the one surface, the first opening includes a first opening area connected to the other surface of the glass substrate and having a diameter decreasing toward the etch stop pattern, and a second opening area connected to the one surface of the glass substrate, and a maximum diameter of the first opening area is greater than a maximum diameter of the second opening area.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is a conceptual diagram of a display device according to one embodiment of the present disclosure;

FIG. 2 is a cross-sectional view taken along line I-I′ of FIG. 1;

FIG. 3 is an enlarged view of portion A of FIG. 2;

FIG. 4A is a first modified example of FIG. 3;

FIG. 4B is a second modified example of FIG. 3;

FIG. 4C is a third modified example of FIG. 3;

FIG. 5 is an enlarged view of portion B of FIG. 2;

FIG. 6 is a view illustrating an etch stop layer surrounding a light-transmitting area and an edge area of a substrate;

FIG. 7 is a cross-sectional view taken along line II-II′ of FIG. 1;

FIG. 8 is a view illustrating a display device according to a first embodiment of the present disclosure;

FIG. 9 is an enlarged view of portion C of FIG. 8;

FIG. 10 is a view illustrating a display panel before forming a light-transmitting area;

FIGS. 11A to 11F are views illustrating a process of etching a substrate to form the light-transmitting area in the display device according to the first embodiment;

FIGS. 12A to 12F are views illustrating a process of etching a substrate to form a light-transmitting area in a display device according to a second embodiment;

FIG. 13 is a view illustrating a display device according to a third embodiment of the present disclosure;

FIGS. 14A to 14F are views illustrating a process of etching a substrate to form a light-transmitting area in the display device according to the third embodiment;

FIG. 15 is a view illustrating a display device according to a fourth embodiment of the present disclosure;

FIG. 16 is a view illustrating the display panel before forming a light-transmitting area;

FIGS. 17A to 17F are views illustrating a process of etching the substrate to form the light-transmitting area in the display device according to the fourth embodiment; and

FIGS. 18A to 18C are views illustrating various forms of etch patterns.

### DETAILED DESCRIPTION

Advantages and features of the present disclosure and implementation methods thereof will be clarified through the following embodiments described with reference to the accompanying drawings. The present disclosure is not limited to the embodiments described below and may be implemented with a variety of different modifications. The embodiments are merely provided to allow those skilled in the art to completely understand the scope of the present disclosure.

The figures, dimensions (e.g., length, width, height, thickness, radius, diameter, area, etc.), ratios, angles, numbers, number of elements, and the like disclosed in the drawings for describing the embodiments of the present disclosure are merely illustrative and thus the present disclosure is not limited to matters illustrated in the drawings.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Throughout the specification, like reference numerals refer to substantially like components. Further, in describing the present disclosure, detailed descriptions of well-known technologies will be omitted when it is determined that they may unnecessarily obscure the gist of the present disclosure.

Terms such as “including,” “having,” and “composed of” used herein are intended to allow other elements to be added unless the terms are used with the term “only.” When a component is expressed in the singular form, it may be construed as the plural form unless otherwise explicitly stated.

Components are interpreted to include an ordinary error range even if not expressly stated.

When the positional or interconnected relationship between two components is described using the terms such as “on,” “above,” “below,” “next to,” “connect or couple,” “crossing or intersecting,” and the like, one or more other components may be interposed between the two components unless the terms are used with the term “immediately” or “directly.”

When the temporal order relationship is described using the terms such as “after,” “subsequent to,” “next,” “before,” and the like, a case which is not continuous may be included unless the term “immediately” or “directly” is used.

To distinguish between components, ordinal numbers such as first, second, and the like may be used before the name of the component, but the function or structure is not limited by these ordinal numbers or component names. For convenience of description, different embodiments may have different ordinal numbers preceding the names of the same component.

The following embodiments may be partially or entirely coupled to or combined with each other and may be interoperated and performed in technically various ways. Each of the embodiments may be independently operable with respect to each other and may be implemented together in related relationships.

Hereinafter, various embodiments of the present disclosure will be described in detail with reference to the accompanying drawings.

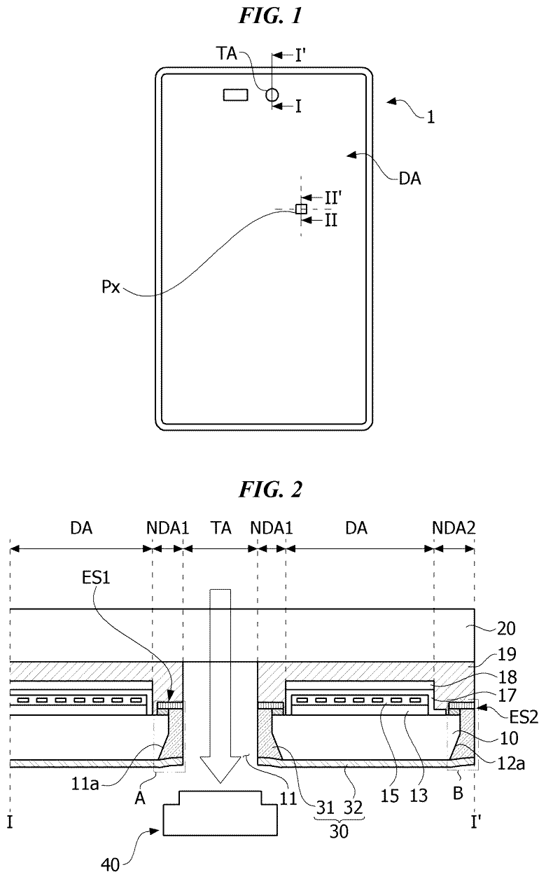

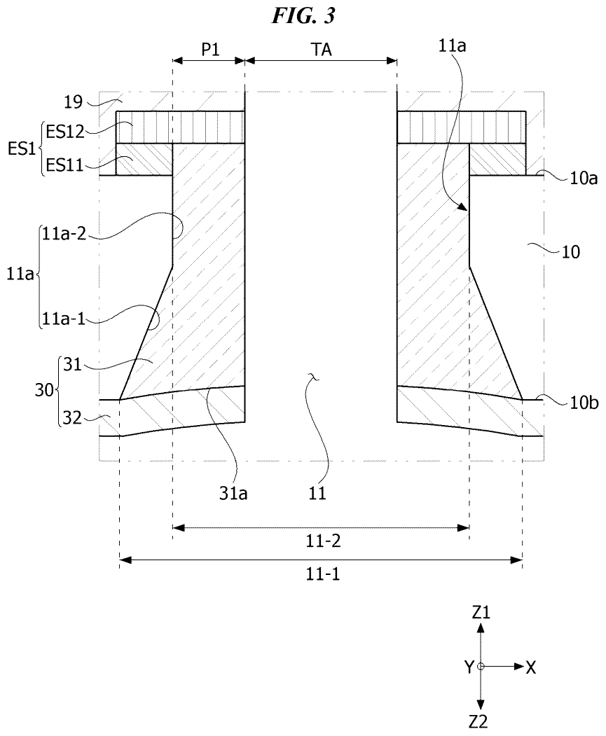

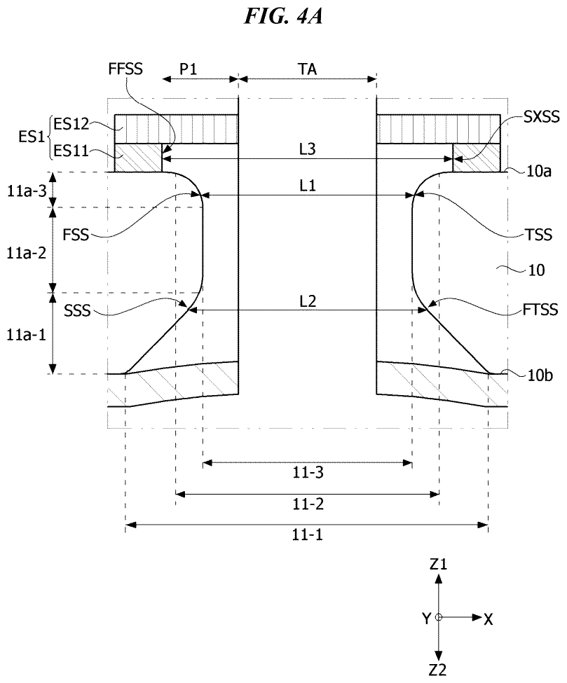

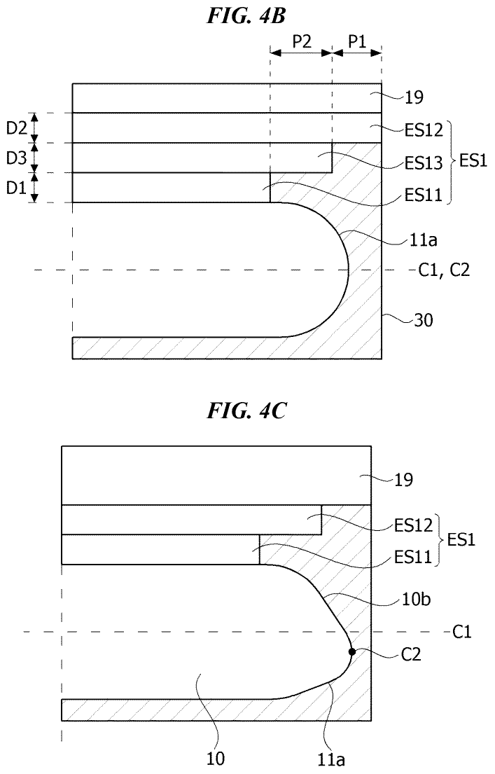

FIG. 1 is a conceptual diagram of a display device according to one embodiment of the present disclosure. FIG. 2 is a cross-sectional view taken along line I-I′ of FIG. 1. FIG. 3 is an enlarged view of portion A of FIG. 2. FIG. 4A is a first modified example of FIG. 3. FIG. 4B is a second modified example of FIG. 3. FIG. 4C is a third modified example of FIG. 3.

Referring to FIGS. 1 to 3, a display device 1 may include a display area DA from which an image is output and a light-transmitting area TA through which light is incident. The light-transmitting area TA may have a hole structure for allowing light to be incident on a sensor 40 disposed below a display panel, but the present disclosure is not necessarily limited thereto.

The display panel may include a circuit portion 13 disposed on a substrate 10, and a light-emitting clement portion 15 disposed on the circuit portion 13. A polarizing plate 19 may be disposed on the light-emitting clement portion 15, and a cover glass 20 may be disposed on the polarizing plate 19. In addition, a touch portion 18 may be disposed between the light-emitting element portion 15 and the polarizing plate 19.

According to the embodiment, the substrate 10 may be a glass substrate having a predetermined strength. However, the substrate 10 is not necessarily limited thereto, may further include a flexible material such as polyimide.

The circuit portion 13 may include a pixel circuit connected to wirings such as data lines, gate lines, power lines, and the like, a gate driving portion connected to the gate lines, and the like.

The circuit portion 13 may include circuit elements such as a transistor implemented as a thin-film transistor (TFT), a capacitor, and the like. The wirings and circuit elements of the circuit portion 13 may be implemented with a plurality of insulating layers, two or more metal layers separated from each other with the insulating layers therebetween, and an active layer including a semiconductor material.

The light-emitting element portion 15 may have a device structure such as an OLED display, a quantum dot display, a micro light-emitting diode (LED) display, or the like. Hercinafter, an OLED structure including an organic compound layer will be described as an example.

The organic compound layer may include a hole injection layer HIL, a hole transport layer HTL, an emission layer EML, an electron transport layer ETL, and an electron injection layer EIL, but the present disclosure is not limited thereto.

When a voltage is applied to an anode and a cathode of an OLED, holes passing through the hole transport layer HTL and electrons passing through the electron transport layer ETL move to the emission layer EML to create excitons, and thus visible light may be emitted from the emission layer EML.

The light-emitting element portion 15 may further include a color filter array disposed on pixels that selectively transmit light of red, green, and blue wavelengths.

The light-emitting clement portion 15 may be covered by a protective film, and the protective film may be covered by an encapsulation portion 17. The protective film and the encapsulation portion 17 may have a structure in which organic insulating layers and inorganic insulating layers are alternately stacked. The inorganic insulating layer may block the penetration of moisture or oxygen. The organic insulating layer may planarize a surface of the inorganic insulating layer. Thus, when the organic and inorganic insulating layers are stacked in multiple layers, a moving path of the moisture or oxygen is longer compared to a single layer, so that the penetration of moisture/oxygen affecting the light-emitting clement portion 15 may be effectively blocked.

The polarizing plate 19 may be disposed on the light-emitting clement portion 15. The polarizing plate 19 can improve outdoor visibility of the display device. The polarizing plate 19 may reduce light reflected from a surface of the display panel and block light reflected from the metal of the circuit portion 13 to improve the brightness of the pixels.

The light-transmitting area TA may be formed between the display areas DA. A first non-display area NDA1 may be disposed to surround the light-transmitting area TA. The first non-display area NDA1 may include a structure of a plurality of dams DAM to protect light-emitting elements in the display area DA from moisture or oxygen that may be introduced from the light-transmitting area TA.

The light-transmitting area TA may have a through-hole structure for injecting light into the sensor 40 such as a camera. However, the present disclosure is not necessarily limited thereto, and pixels having a low density may be disposed in the light-transmitting area TA.

The substrate 10 may include a first opening 11 disposed in the light-transmitting area TA. Accordingly, the first opening 11 of the substrate 10 overlaps the light-transmitting area TA from a plan view. The first opening 11 may have a tapered shape that narrows in width as it approaches the cover glass 20. However, the first opening 11 is not necessarily limited thereto, and may have a tapered shape that increases in width as it approaches the cover glass 20, or may be constant in width in a thickness direction. The tapered shape of the first opening 11 may be variously changed by the type of an etchant and an etching method.

A first etch stop pattern ES1 may be disposed on the first opening 11 of the substrate 10. In addition, a second etch stop pattern ES2 may be disposed on an edge of the substrate 10. The first etch stop pattern ES1 and the second etch stop pattern ES2 may prevent an etchant from penetrating into the panel when etching the substrate 10.

The first etch stop pattern ES1 and the second etch stop pattern ES2 may include an organic material and/or a metal material that are resistant to an etchant. As an example, the etch stop pattern may include one selected from the group consisting of a polyester-based polymer, a silicone-based polymer, an acrylic-based polymer, a polyolefin-based polymer, and a copolymer thereof. In addition, a metal material that is chemically resistant to a hydrofluoric acid-based etching solution, such as molybdenum, may be included. However, the etch stop pattern is not necessarily limited thereto, and may include various materials that are resistant to the etchant.

The first etch stop pattern ES1 and the second etch stop pattern ES2 may be formed by extending from at least one of the layers constituting the circuit portion 13, the light-emitting clement portion 15, the encapsulation portion 17, and the touch portion 18. That is, the first etch stop pattern ES1 and the second etch stop pattern ES2 may be dummy layers extending from the circuit portion 13, the light-emitting element portion 15, the encapsulation portion 17, or the touch portion 18. With this configuration, the etch stop pattern may be formed without adding a separate process.

According to the embodiment, the first etch stop pattern ES1 may include a protrusion P1 (also referred to as a first protrusion P1 of the second etch stop layer ES12) protruding toward an inner side of the first opening 11. The protrusion P1 may be defined as a part more protruding toward the light-transmitting area than an upper surface of the first opening 11. The protrusion P1 may be formed in a process of laser cutting the etch stop pattern.

A coating layer 30 may be formed on a back surface of the substrate 10. The coating layer 30 may be formed of an organic material including a polyester-based polymer or an acrylic-based polymer.

The coating layer 30 may include a side coating layer 31 formed on an inner side surface of the first opening 11, and a back coating layer 32 disposed on a lower portion of the substrate. A lower surface 31a of the side coating layer 31 may be formed to be concave toward the etch stop pattern. However, the side coating layer 31 is not necessarily limited thereto, and may not be contracted depending on the material. Thus, the lower surface 31a of the side coating layer 31 may be substantially flat even after curing is completed.

The first etch stop pattern ES1 may include a first etch stop layer ES11 surrounding the first opening 11 and a second etch stop layer ES12 disposed on the first etch stop layer ES11.

The second etch stop layer ES12 may include the protrusion P1 extending further toward the light-transmitting area TA than the first etch stop layer ES11. With this configuration, the sharpness of the edge of the substrate 10 can be mitigated by exposing and etching an upper surface of the substrate 10 in the etching process. That is, a side surface 11a of the substrate 10 may be formed to be gently rounded, thereby improving the strength of the side surface of the substrate 10 and preventing cracking.

As shown in FIG. 3, the protrusion P1 of the second etch stop layer ES12 does not overlap the first etch stop layer ES11 from a plan view. That is, the protrusion P1 of the second etch stop layer ES12 extends further towards the opening 11 or further towards the light-transmitting area TA than the first etch stop layer ES11.

The first etch stop layer ES11 and the second etch stop layer ES12 may be made of different materials. In addition, chemical resistance of the second etch stop layer ES12 may be higher than chemical resistance of the first etch stop layer ES11. Here, the term “chemical resistance” may refer to the degree to which the etch stop layer does not react with an etching solution. Thus, the etch stop layer having high chemical resistance may be etched relatively less.

The first etch stop layer ES11 may be formed of a metal material such as molybdenum, and the second etch stop layer ES12 may be formed of an organic material such as polyimide, but the present disclosure is not necessarily limited thereto.

The first etch stop layer ES11 may be thinner than the second etch stop layer ES12. As an example, the first etch stop layer ES11 may be the same layer as a light-blocking layer formed in the display area DA, and the second etch stop layer ES12 may be the same layer as a planarization layer formed in the display area DA. However, the present disclosure is not necessarily limited thereto, and the first etch stop layer ES11 and the second etch stop layer ES12 may be formed of various organic insulating layers and metal layers in the display area DA. In addition, each of the first etch stop layer ES11 and the second etch stop layer ES12 may include a plurality of layers.

The first opening 11 may include a first opening area 11-1 connected to a lower surface 10b of the substrate 10 and a second opening area 11-2 connected to an upper surface 10a of the substrate 10. The first opening area 11-1 may correspond to a maximum diameter of a lower side surface 11a-1 of the first opening 11, and the second opening area 11-2 may correspond to a diameter of an upper side surface 11a-2 of the first opening 11.

The first opening area 11-1 may be formed to have a diameter that decreases toward the first etch stop pattern ES1, and the second opening area 11-2 may be formed to have a relatively constant diameter. The meaning that the diameter of the second opening area 11-2 is constant may include, in addition to having a substantially constant diameter, a relatively small change in diameter compared to that of the first opening area 11-1. That is, the change in diameter in the second opening area 11-2 may be smaller than the change in diameter in the first opening area 11-1.

The upper side surface 11a-2 of the second opening area 11-2 may be disposed on the same vertical plane as a side surface of the first etch stop layer ES11. According to the embodiment, the sharpness of the edge of the substrate 10 can be mitigated by disposing the first etch stop layer ES11 on a back side of the second etch stop layer ES12 and exposing and etching the upper surface of the substrate 10.

The second etch stop layer ES12 and the side coating layer 31 may include an opening hole formed in an area corresponding to the light-transmitting area TA. Thus, a side surface of the side coating layer 31, a side surface of the back coating layer 32, and a side surface of the second etch stop layer ES12 may be disposed on the same vertical plane.

Referring to FIG. 4A, the first opening 11 may include a first opening area 11-1 having a diameter that decreases toward the first etch stop pattern ES1, a second opening area 11-2 that increases in diameter as it approaches the first etch stop pattern ES1, and a third opening area 11-3 disposed between the first opening area 11-1 and the second opening area 11-2.

The first opening area 11-1 may correspond to a diameter of a lower side surface 11a-1 of the first opening 11, the second opening area 11-2 may correspond to a diameter of an upper side surface 11a-3 of the first opening 11, and the third opening area 11-3 may correspond to a diameter of a central side surface 11a-2 of the first opening 11.

The first opening area 11-1 may be connected to the lower surface 10b of the substrate 10 and may decrease in width in a direction (a Z1 direction) toward the first etch stop pattern ES1. A side surface of the first opening area 11-1 may be a straight line, but is not necessarily limited thereto, and may have a curvature.

The second opening area 11-2 may be connected to the upper surface 10a of the substrate 10 and may increase in width in the direction toward the first etch stop pattern ES1. That is, the width of the second opening area 11-2 may become smaller in a direction (a Z2 direction) from the upper surface 10a to the lower surface 10b of the substrate 10. The side surface of the second opening area 11-2 may be a straight line, but is not necessarily limited thereto, and may have a curvature.

According to the embodiment, a maximum diameter of the first opening area 11-1 may be greater than a maximum diameter of the second opening area 11-2. However, the present disclosure is not necessarily limited thereto, and the maximum diameter of the second opening area 11-2 may be greater than the maximum diameter of the first opening area 11-1. Alternatively, the maximum diameter of the first opening area 11-1 and the maximum diameter of the second opening area 11-2 may be the same.

Referring to FIG. 4A, the opening of the substrate 10 defines one or more side surfaces of the substrate. As shown, the one or more side surfaces include a first side surface FSS and a second side surface SSS adjacent to the first side surface FSS at a first side of the opening (e.g., left side of the opening as seen from FIG. 4A). The one or more side surfaces further include a third side surface TSS and a fourth side surface FTSS adjacent to the third side surface TSS at a second side of the opening that is opposite and facing the first side of the opening. That is, the second side refers to the right side of the opening as seen from FIG. 4A.

Here, the first side surface FSS is opposite to and facing the third side surface TSS, and the second side surface SSS is opposite to and facing the fourth side surface FTSS.

A first diameter L1 of the opening may be defined by a distance between the first side surface FSS and third side surface TSS as shown in FIG. 4A. Similarly, a second diameter L2 may be defined by a distance between the second side surface SSS and fourth side surface FTSS.

As shown, in some embodiments, the first diameter L1 and the second diameter L2 may be different from each other due to the various curvatures of the side surfaces of the substrate 10 (e.g., 11a-1, 11a-2, 11a-3, FSS, SSS, TSS, FTSS).

Referring to FIG. 4A, the first etch stop layer ES11 includes a fifth side surface FFSS and a sixth side surface SXSS opposite to and facing the fifth side surface FFSS. Here, the sixth side surface SXSS of the first etch stop layer ES11 is located on the other side of the opening of the substrate 10, namely the second side or the right side of the opening.

A third diameter L3 may be defined by a distance between the fifth side surface FFSS and the sixth side surface SXSS of the first etch stop layer ES11. In some embodiments, the third diameter L3 is different from the first diameter L1 and the second diameter L2.

The difference in diameters L1, L2, and L3 may create a varying shape of the opening as shown in FIG. 4A. Various other shapes can be formed based on etching the substrate 10 and the etch stop patterns ES1 to have different diameters.

In some embodiments, as previously noted above, the first side surface FSS and the second side surface SSS can have different curvatures from each other. Similarly, side surfaces 11a-1, 11a-2, 11a-3 can also have different curvatures from each other.

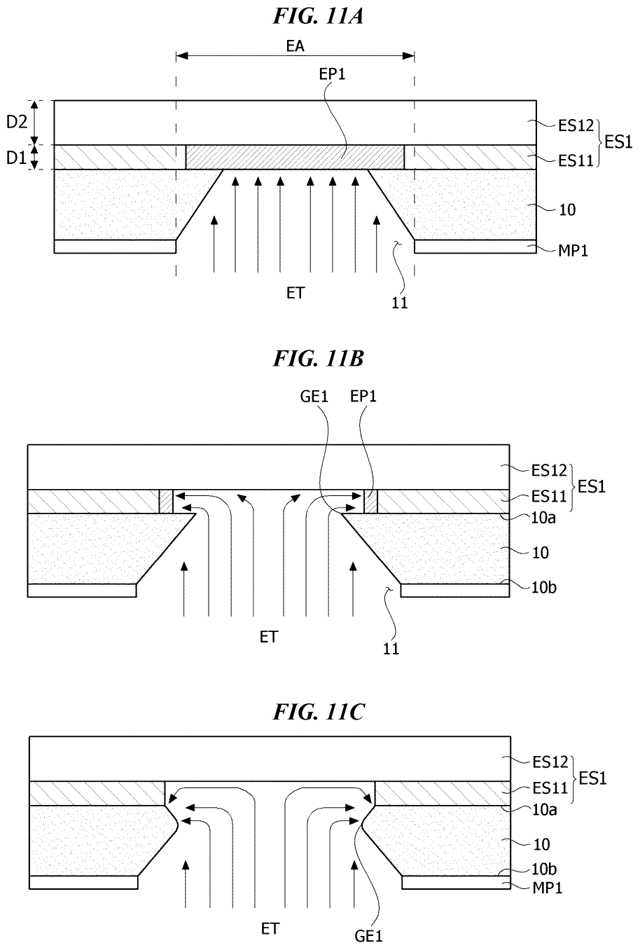

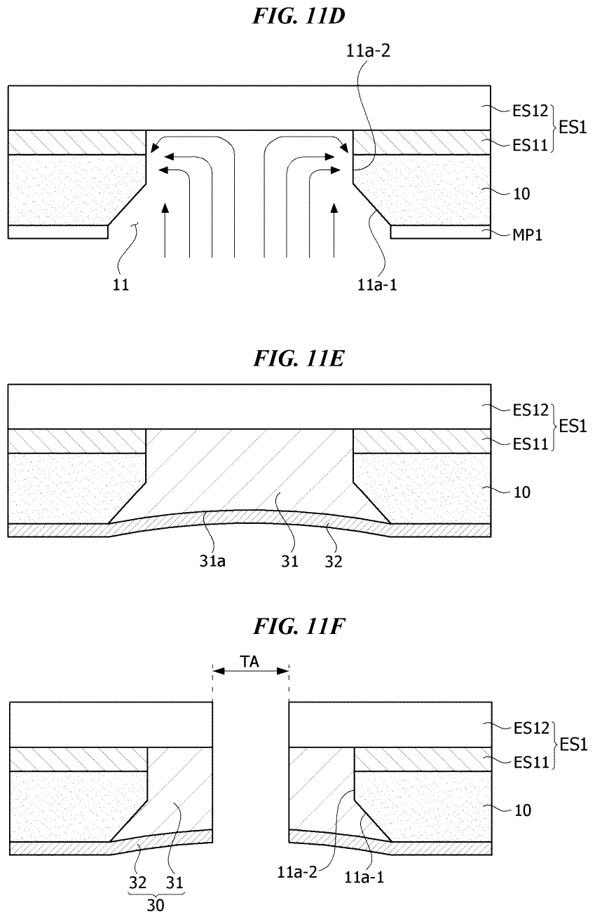

Referring to FIG. 3, the first etch stop layer ES11 has a thickness (or a height) DD1 in the z1-axis direction and the second etch stop layer ES12 has a thickness (or a height) DD2 in the z1-axis direction. In some embodiments, the thickness DD1 of the first etch stop layer ES11 and the thickness DD2 of the second etch stop layer ES12 may be the same. However, in other embodiments, as shown in FIGS. 11, 12, and 14, the thickness DD1 of the first etch stop layer ES11 may be thinner than the thickness DD2 of the second etch stop layer ES12.

Referring to FIG. 4B, the first etch stop pattern ES1 may further include a third etch stop layer ES13 disposed between the first etch stop layer ES11 and the second etch stop layer ES12. The third etch stop layer ES13 may be made of the same material as the first etch stop layer ES11 and/or the second etch stop layer ES12, or a different material. As an example, the third etch stop layer ES13 may have a greater chemical resistance to an etching solution than the first etch stop layer. The etch stop pattern may be formed by stacking etch stop layers of the same or different materials.

As shown in FIG. 4B, the protrusion P1 of the second etch stop layer ES12 does not overlap the first etch stop layer ES11 from a plan view. That is, the protrusion P1 of the second etch stop layer ES12 extends further towards the opening 11 or further towards the light-transmitting area TA than the first etch stop layer ES11. Similarly, a protrusion P2 of the third etch stop layer ES13 does not overlap the first etch stop layer ES11 from a plan view. That is, the protrusion P2 of the third etch stop layer ES13 extends further towards the opening 11 or further towards the light-transmitting area TA than the first etch stop layer ES11. Here, the protrusion P1 of the second etch stop layer ES12 extends further towards the opening 11 or further towards the light-transmitting area TA than the protrusion P2 of the third etch stop layer ES13. Accordingly, the protrusion P1 of the second etch stop layer ES12 does not overlap the protrusion P2 of the third etch stop layer ES13 from a plan view. That is, the protrusion P1 of the second etch stop layer ES12 extends further towards the opening 11 or further towards the light-transmitting area TA than the protrusion P2 of the third etch stop layer ES13.

The third etch stop layer ES13 has a thickness (or height) D3. In some embodiments, the thickness D3 may be the same as thickness D1 or D2. However, in other embodiments, the thickness D3 may be different from thickness D1 or D2. For example, thickness D3 may be smaller than thickness D2 and smaller than thickness D1. In other examples, thickness D3 may be smaller than thickness D2 but greater than thickness D1.

The side surface 11a of the first opening 11 may further protrude toward the light-transmitting area than the first etch stop layer ES11. Thus, the upper surface of the substrate 10 may be etched to mitigate the sharpness.

The side surface 11a of the first opening 11 of the substrate 10 may be formed to be symmetrical with respect to a thickness center C1 of the substrate 10. Accordingly, an area C2 most protruding from the side surface of the first opening 11 may match the thickness center C1 of the substrate 10. However, the present disclosure is not necessarily limited thereto, and as shown in FIG. 4C, the area C2 most protruding from the side surface of the first opening 11 may be disposed to be misaligned with the thickness center C1 of the substrate 10. That is, the area C2 most protruding from the side surface of the first opening 11 may be disposed above or below the thickness center C1 of the substrate 10. In FIG. 4C, it is exemplarily illustrated that the area C2 most protruding from the side surface of the first opening 11 is disposed below the thickness center C1 of the substrate 10.

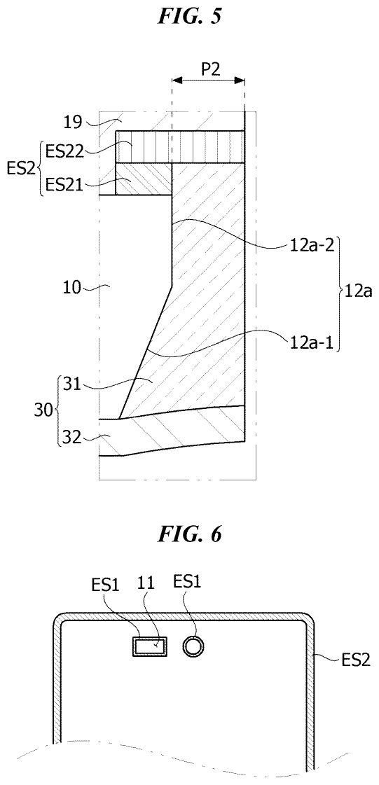

Referring to FIGS. 2 and 5, a second non-display area NDA2 may be disposed at an edge of the display panel. The second non-display area NDA2 may be a margin portion required to separate a plurality of panels from a mother substrate.

The substrate 10 may include a second inclined surface 12a formed at the edge thereof. The second inclined surface 12a may include a 2-1 inclined surface 12a-1 inclined such that the width of the first opening 11 decreases toward the second etch stop pattern ES2, and a 2-2 inclined surface 12a-2 formed relatively vertically. The second inclined surface 12a may have the same angle as the side surface 11a formed in the first opening 11. The first opening 11 and the second inclined surface 12a are formed simultaneously by an etchant, so that the first opening 11 and the second inclined surface 12a may have the same inclination angle and etching depth.

According to the embodiment, the first opening 11 may be formed in a substrate of each display panel simultaneously in a process of separating a plurality of display panels by etching a mother substrate using an etchant. Accordingly, the opening may be formed without additional equipment and without reducing rigidity. In addition, various shapes of openings may be formed by changing a mask pattern.

The second etch stop pattern ES2 disposed in the second non-display area NDA2 may prevent an etchant from penetrating into a plurality of display panels when etching a mother substrate to separate the plurality of display panels.

The second etch stop pattern ES2 may extend from at least one of the layers of the circuit portion 13, the light-emitting clement portion 15, the encapsulation portion 17, and the touch portion 18. Alternatively, the second etch stop pattern ES2 may be formed simultaneously in a process of forming at least one of the layers of the circuit portion 13, the light-emitting element portion 15, the encapsulation portion 17, and the touch portion 18. With this configuration, the second etch stop pattern ES2 may be formed without adding a separate process.

According to the embodiment, the second etch stop pattern ES2 may include a protrusion P2 protruding outwardly from the second inclined surface 12a. The protrusion P2 may prevent damage to the display panel when laser cutting the second etch stop pattern ES2.

FIG. 6 is a view illustrating a shape in which the etch stop layer surrounds the light-transmitting area.

Referring to FIG. 6, the first etch stop pattern ES1 may be disposed to entirely surround the periphery of the first opening 11. In addition, the second etch stop pattern ES2 may be disposed to entirely surround an outer peripheral surface of the display panel.

According to the embodiment, since the first etch stop pattern ES1 is disposed to entirely surround the periphery of the first opening 11 and the second etch stop pattern ES2 is disposed to entirely surround the outer circumferential surface of the display panel, an etchant may be prevented from penetrating into the panel in a case in which a through hole is formed inside the substrate simultaneously when a mother substrate is cut.

According to the embodiment, the opening of various shapes may be formed in the glass substrate using etching. Thus, compared to conventional scribing, breaking, and grinding techniques, there is an advantage of being able to form various openings while maintaining the rigidity of the substrate. In addition, there is an advantage of being able to form the opening simultaneously when processing the side surface of the substrate 10 to form notches or roundings on the side surface of the substrate 10.

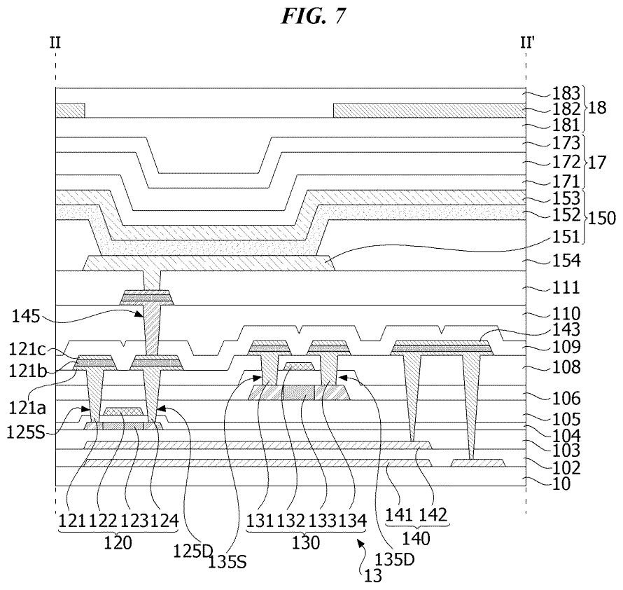

FIG. 7 is a cross-sectional view taken along line II-II′ of FIG. 1.

Referring to FIG. 7, in the display area DA, a first transistor 120 and a second transistor 130 may be disposed on the substrate 10, and a light-emitting element portion 150 may be disposed on a planarization layer 111.

A first light-blocking layer 141 may be disposed on the substrate 10. The first light-blocking layer 141 may include molybdenum and/or aluminum. The first light-blocking layer 141 may block light entering a first semiconductor layer 123 or a second semiconductor layer 133.

A multi-buffer layer 102 may delay the diffusion of moisture or oxygen penetrating into the substrate 10, and may be formed by alternately stacking silicon nitride (SiNx) and silicon oxide (SiOx) at least once.

The second light-blocking layer 142 may be disposed on the multi-buffer layer 102. The second light-blocking layer 142 may include molybdenum and/or aluminum. The second light-blocking layer 142 may block light entering the first semiconductor layer 123 or the second semiconductor layer 133.

An active buffer layer 103 may protect the first semiconductor layer 123, and serve to block various types of defects introduced from the substrate 10. The active buffer layer 103 may be formed of a-Si, silicon nitride (SiNx), silicon oxide (SiOx), or the like.

The first semiconductor layer 123 of the first transistor 120 may be formed of a polycrystalline semiconductor layer, and the first semiconductor layer 123 may include a channel area, a source area, and a drain area.

The polycrystalline semiconductor layer has higher mobility than an amorphous semiconductor layer and an oxide semiconductor layer, and thus has low energy power consumption and excellent reliability. Due to these advantages, the polycrystalline semiconductor layer may be used for a driving transistor.

A first gate electrode 122 may be disposed on a lower gate insulating layer 104 and may be disposed to overlap the first semiconductor layer 123.

The second transistor 130 may be disposed on a lower interlayer insulating layer 105. An upper gate insulating layer 106 for insulating a second gate electrode 132 from the second semiconductor layer 133 may be disposed on the second semiconductor layer 133.

An upper interlayer insulating layer 108 may be disposed on the second gate electrode 132. Each of the first gate electrode 122 and the second gate electrode 132 may be formed as a single layer or a multilayer made of one selected from among molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

The lower interlayer insulating layer 105 may be formed as an inorganic insulating layer having a higher hydrogen particle content than the upper interlayer insulating layer 108. For example, the lower interlayer insulating layer 105 may be made of silicon nitride (SiNx) formed through a deposition process using NH3 gas, and the upper interlayer insulating layer 108 may be made of silicon oxide (SiOx). Hydrogen particles included in the lower interlayer insulating layer 105 may be diffused into the polycrystalline semiconductor layer during a hydrogenation process to fill pores in the polycrystalline semiconductor layer with hydrogen. Accordingly, the polycrystalline semiconductor layer may be stabilized, thereby preventing degradation in characteristics of the first transistor 120.

After an activation and hydrogenation process of the first semiconductor layer 123 of the first transistor 120, the second semiconductor layer 133 of the second transistor 130 may be formed, and in this case, the second semiconductor layer 133 may be formed of an oxide semiconductor. Since the second semiconductor layer 133 is not exposed to a high-temperature atmosphere of the activation and hydrogenation process of the first semiconductor layer 123, damage to the second semiconductor layer 133 may be prevented, which may improve reliability.

After the upper interlayer insulating layer 108 is disposed, a first source contact hole 125S and a first drain contact hole 125D may be respectively formed to correspond to a source area and a drain area of the first transistor, and a second source contact hole 135S and a second drain contact hole 135D may be respectively formed to correspond to a source region and a drain region of the second transistor 130.

The first source contact hole 125S and the first drain contact hole 125D may be continuously formed from the upper interlayer insulating layer 108 to the lower gate insulating layer 104, and the second source contact hole 135S and the second drain contact hole 135D may also be formed in the second transistor 130.

A first source electrode 121 and a first drain electrode 124 corresponding to the first transistor 120, and a second source electrode 131 and a second drain electrode 134 corresponding to the second transistor 130 may be simultaneously formed. This can reduce the number of processes to form the source and drain electrodes of each of the first transistor 120 and the second transistor 130.

The first source and drain electrodes 121 and 124 and the second source and drain electrodes 131 and 134 may be formed as a single layer or a multilayer made of at least one selected from among molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

The first source and drain electrodes 121 and 124 and the second source and drain electrodes 131 and 134 may have a three-layered structure, and for example, the first source electrode 121 may include a first layer 121a including Ti, a second layer 121b including Al, and a third layer 121c including Ti, and other source and drain electrodes may have the same structure as the first source electrode 121.

A storage capacitor 140 may be disposed between the first transistor 120 and the second transistor 130. According to the embodiment, the storage capacitor 140 may be formed using the first light-blocking layer 141 and the second light-blocking layer 142. As an example, the second light-blocking layer 142 may be electrically connected to a pixel circuit through a storage supply line 143. However, the structure of the storage capacitor 140 is not necessarily limited thereto, and may be variously modified using other two metal layers.

The storage supply line 143 may be formed to be coplanar with the first source and drain electrodes 121 and 124 and the second source and drain electrodes 131 and 134 and made of the same material as the first source and drain electrodes 121 and 124 and the second source and drain electrodes 131 and 134, and accordingly, the storage supply line 143 may be formed simultaneously with the first source and drain electrodes 121 and 124 and the second source and drain electrodes 131 and 134 through the same mask process.

A protective film 109 may be formed by depositing an inorganic insulating material such as SiNx or SiOx on an entire surface of the substrate 10 on which the first source and drain electrodes 121 and 124, the second source and drain electrodes 131 and 134, and the storage supply line 143 are formed.

A first planarization layer 110 may be formed on the protective film 109. Specifically, the first planarization layer 110 may be disposed by applying an organic insulating material such as an acrylic-based resin onto the entire surface of the protective film 109.

After the protective film 109 and the first planarization layer 110 are disposed, a contact hole exposing the first source electrode 121 or the first drain electrode 124 of the first transistor 120 may be formed through a photolithography process. A connection electrode 145 made of a material including Mo, Ti, Cu, AlNd, Al, Cr, or an alloy thereof may be disposed in an area of the contact hole exposing the first drain electrode 124.

A second planarization layer 111 may be disposed on the connection electrode 145, and a contact hole exposing the connection electrode 145 may be formed in the second planarization layer 111 to arrange a light-emitting element 150 connected to the first transistor 120. The connection electrode 145 may be formed in a multi-layer structure in the same manner as the first source and drain electrodes 121 and 124.

The light-emitting element 150 may include an anode 151 connected to the first drain electrode 124 of the first transistor 120, at least one light-emitting stack 152 formed on the anode 151, and a cathode 153 formed on the light-emitting stack 152.

The light-emitting stack 152 may include a hole injection layer, a hole transport layer, an emission layer, an electron transport layer, and an electron injection layer, and, in a tandem structure in which a plurality of emission layers overlap each other, a charge generation layer may be additionally disposed between the emission layer and the emission layer. The emission layer may emit light having different colors for each subpixel.

The anode 151 may be connected to the connection electrode 145 exposed through a contact hole passing through the second planarization layer 111. The anode 151 may be formed in a multi-layered structure including a transparent conductive film and an opaque conductive film having high reflection efficiency. The transparent conductive film may be made of a material having a relatively large work function value, such as indium-tin-oxide (ITO) or indium-zinc-oxide (IZO), and the opaque conductive film may have a single-layered or multi-layered structure including Al, Ag, Cu, Pb, Mo, Ti, or an alloy thereof.

For example, the anode 151 may be formed in a structure in which a transparent conductive film, an opaque conductive film, and a transparent conductive film are sequentially stacked or in a structure in which a transparent conductive film and an opaque conductive film are sequentially stacked.

The anode 151 may be disposed in an emission area provided by a bank 154 as well as on the second planarization layer 111 to overlap a pixel circuit area in which the first and second transistors 120 and 130 and the storage capacitor 140 are disposed, thereby increasing an area for emitting light.

The light-emitting stack 152 may be formed by stacking the hole transport layer, the organic emission layer, and the electron transport layer on the anode 151 in this order or in a reverse order. In addition, the light-emitting stack 152 may further include a charge generation layer and may include first and second light-emitting stacks facing each other with the charge generation layer interposed therebetween.

The bank 154 may be formed to expose the anode 151. The bank 154 may be made of an organic material such as photo acrylic and may include a translucent material, but the present disclosure is not limited thereto. The bank 154 may be made of an opaque material to prevent light interference between the subpixels.

The cathode 153 may be formed on an upper surface of the light-emitting stack 152 to face the anode 151 with the light-emitting stack 152 interposed therebetween. When the cathode 153 is applied to a top emission type organic light-emitting display device, the cathode 153 may be formed of a transparent conductive film by thinly forming ITO, IZO, or magnesium-silver (Mg—Ag).

The encapsulation portion 17 for protecting the light-emitting element 150 may be formed on the cathode 153. Since the light-emitting element 150 reacts with external moisture or oxygen due to the characteristics of an organic material of the light-emitting stack 152, dark-spots or pixel shrinkage may occur. In order to prevent the dark-spots or pixel shrinkage, the encapsulation portion 17 may be disposed on the cathode 153.

The encapsulation portion 17 may include a first inorganic insulating layer 171, a foreign material compensation layer 172, and a second inorganic insulating layer 173.

The touch portion 18 may be disposed on the encapsulation portion 17. The touch portion 18 may include a first touch planarization layer 181, a touch electrode 182, and a second touch planarization layer 183. The first touch planarization layer 181 and the second touch planarization layer 183 may be disposed to eliminate a stepped portion at a point at which the touch electrode 182 is disposed and to allow the touch electrode 182 to be electrically insulated well.

According to embodiments, by disposing the first transistor 120 made of low-temperature polycrystalline silicon and the second transistor 130 made of an oxide semiconductor in different layers, thin-film transistors (TFTs) having different driving characteristics may be disposed in the display device 1. However, the present disclosure is not necessarily limited thereto, and only the thin-film transistors having the same driving characteristic may be used and various circuit structures may be provided.

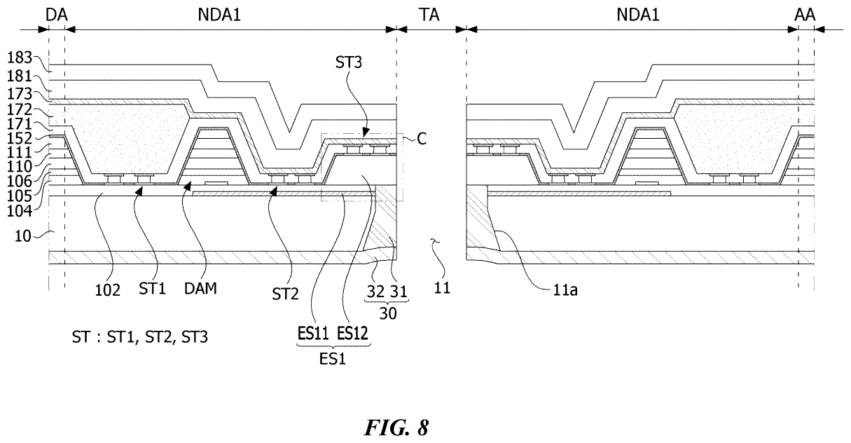

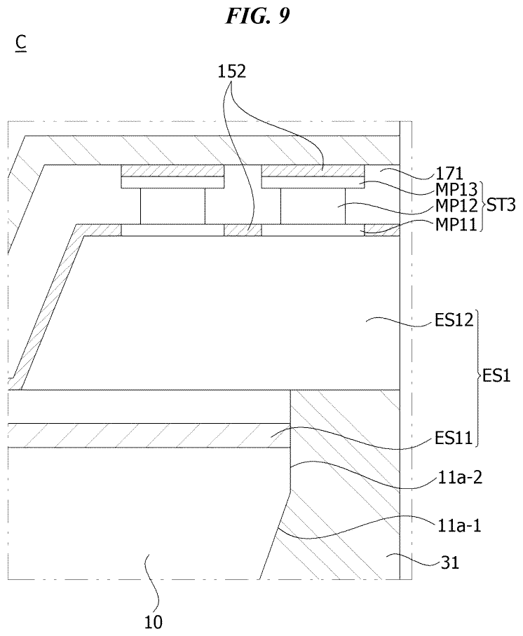

FIG. 8 is a view illustrating a display device according to a first embodiment of the present disclosure. FIG. 9 is an enlarged view of portion C of FIG. 8.

Referring to FIGS. 8 and 9, a light-transmitting area TA in which various sensors are disposed may be formed in a circular shape, and a first non-display area NDA1 may be disposed around the light-transmitting area. However, the light-transmitting area TA is not necessarily limited thereto, and may have various shapes such as a polygonal shape and an elliptical shape, and the shape of the first non-display area NDA1 may also vary accordingly.

Dams DAM and a plurality of protruding patterns ST may be formed in the first non-display area NDA1 by using a plurality of layers extending from a display area. The number of dams DAM and protruding patterns ST is not particularly limited.

The dams DAM and the protruding patterns ST may each be disposed in a closed loop shape surrounding the light-transmitting area TA. With this configuration, moisture can be prevented from penetrating into the display area through the light-transmitting area TA.

A first etch stop pattern ES1 may prevent an etching solution from penetrating into a panel during etching a substrate 10. The first etch stop pattern ES1 may include an organic insulating layer or a metal layer which is not etched by the etching solution. The metal layer may include molybdenum (Mo) having a strong chemical resistance to the etching solution.

A plurality of protruding patterns ST may be disposed in the first non-display area NDA1. The protruding pattern ST is formed to have an undercut shape to disconnect a light-emitting stack 152 formed in the first non-display area NDA1.

The plurality of protruding patterns ST may include a first protruding pattern ST1 and a second protruding pattern ST2 disposed in a moisture-permeating prevention area NDA11, and a third protruding pattern ST3 disposed in a dummy area NDA12.

A plurality of first protruding patterns ST1 may be disposed between a display area DA and the dam DAM, and a plurality of second protruding patterns ST2 may be disposed between the dam DAM and the first etch stop pattern ES1. The third protruding patterns ST3 may be disposed on the first etch stop pattern ES1.

The plurality of first protruding patterns ST1, the plurality of second protruding patterns ST2, and the third protruding patterns ST3 may have the same shape, but the present disclosure is not necessarily limited thereto. As an example, the first protruding pattern ST1 and the second protruding pattern ST2 may have the same shape, but the third protruding pattern ST3 may have a different shape. Each of the protruding patterns ST1, ST2, and ST3 may be variously modified as long as it has a structure capable of disconnecting the light-emitting stack 152.

The substrate 10 may have a first opening 11 formed in an area corresponding to the light-transmitting area TA. A diameter of the first opening 11 may be greater than that of the light-transmitting area TA.

A side coating layer 31 may be formed on a side surface 11a of the first opening 11. The side coating layer 31 may cover the side surface of the first opening 11. The first etch stop pattern ES1 may be disposed on the side coating layer 31.

The side coating layer 31 may be made of an organic material that absorbs light. In one embodiment, the side coating layer 31 may include an organic material having an optical density (OD) of 1.0 or more.

A back coating layer 32 may be disposed on a lower portion of the substrate 10 and a lower portion of the side coating layer 31. The back coating layer 32 may be formed to further extend from a back surface of the substrate 10 up to the side coating layer 31.

In the display device according to the embodiment, a bonding strength of the back coating layer 32 may be improved by forming the back coating layer 32 to cover up to the side coating layer 31. The back coating layer 32 may be formed only on the back surface of the substrate 10 to protect the substrate 10. However, the back coating layer 32 made of an organic material has a relatively low bonding strength with the substrate 10, and thus may be delaminated from the substrate 10 by an external environment or impact. Thus, the bonding strength of the back coating layer 32 can be improved by allowing the back coating layer 32 to be in contact with the side coating layer 31 made of an organic material at an outer periphery of the substrate 10. Accordingly, the back coating layer 32 can be prevented from delaminating from the substrate 10.

According to the embodiment, a side surface of the light-transmitting area TA may be vertically formed. That is, a side surface of the back coating layer 32, a side surface of the side coating layer 31, a side surface of the first etch stop pattern ES1, and a side surface of a polarizing plate 19, which form the side surface of the light-transmitting area TA, may be laser cut and formed to have the same vertical plane.

The plurality of protruding patterns ST may each have a first pattern layer MP11, a second pattern layer MP12, and a third pattern layer MP13 stacked in sequence. The first pattern layer MP11 and the third pattern layer MP13 may be made of titanium (Ti), and the second pattern layer MP12 may be made of aluminum (Al).

The protruding pattern ST according to the embodiment may be made of the same material as source and drain electrodes 121 and 124 or a connection electrode 145 in the display area. That is, the plurality of protruding patterns ST may be simultaneously formed when the connection electrode 145 is formed, and then may be etched to be separated into the plurality of protruding patterns ST. At this time, the second pattern layer MP12 made of an aluminum material may be etched relatively more due to the difference in etching reaction speed. Accordingly, a width of the second pattern layer MP12 may be smaller than a width of the third pattern layer MP13, thereby having the undercut shape. Accordingly, the light-emitting stack 152 formed on the plurality of protruding patterns ST may not be continuously formed and may be disconnected between the plurality of protruding patterns ST. Thus, a moisture penetration path may be blocked.

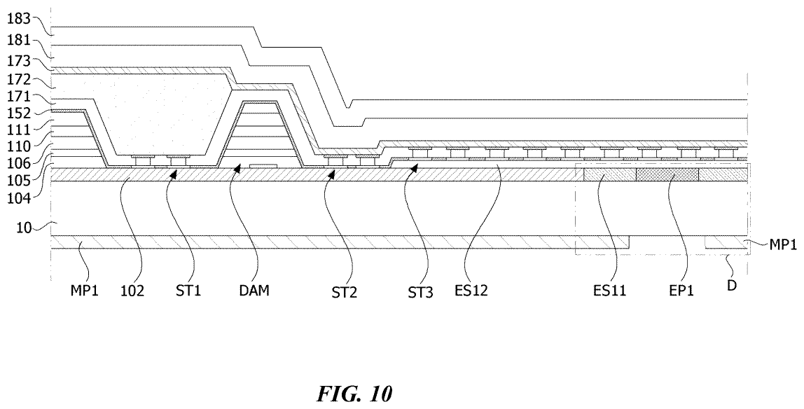

FIG. 10 is a view illustrating the display panel before forming the light-transmitting area. FIGS. 11A to 11F are views illustrating a process of etching the substrate to form the light-transmitting area in the display device according to the first embodiment.

Referring to FIGS. 10 and 11A, a mask pattern MP1 may be formed on a lower portion of an etch area EA from which a substrate 10 is removed, and a partial area of the substrate 10 may be exposed. A first etching pattern EP1 may be formed on the etch area EA. A first etch stop layer ES11 may be disposed to surround the first etching pattern EP1. A second etch stop layer ES12 may be disposed on the first etching pattern EP1 and the first etch stop layer ES11.

The first etching pattern EP1 may include an inorganic material that is relatively well etched by an etching solution, and the first etch stop layer ES11 and the second etch stop layer ES12 may include a material that is not well etched by the etching solution. As an example, the first etch stop layer ES11 may include an inorganic material such as a-Si or p-Si, or a metal such as molybdenum (Mo). The second etch stop layer ES12 may include an organic material.

As an example, the first etching pattern EP1 may include an active buffer layer, a gate electrode, a multi-buffer layer, source/drain electrodes, and the like in a display area. The first etch stop layer ES11 may include a first light-blocking layer and a second light-blocking layer in the display area.

When the etching process is performed, the etch area EA of the substrate 10 may be etched from the lower portion thereof. An etching solution ET may be a hydrofluoric acid solution, but the present disclosure is not necessarily limited thereto. A first opening 11 may be formed in a tapered shape whose diameter becomes smaller toward an upper portion of the etch area EA of the substrate 10. When the etch area EA of the substrate 10 is etched, the first etching pattern EP1 may be exposed.

Referring to FIG. 11B, when the first etching pattern EP1 is etched by the etching solution, an upper surface 10a of the substrate 10 adjacent to the first opening 11 may be gradually exposed. As the etching process further proceeds, an edge GE1 formed at a side surface of the first opening 11 may also be gradually etched.

Referring to FIGS. 11C and 11D, as the etching process further proceeds, the edge GE1 disposed at the upper surface of the substrate 10 may be substantially removed. As the etching process continues, the edge GE1 formed in the first opening 11 is gradually etched, and sharpness may be mitigated. When the sharpness is mitigated, the entire side surface of the first opening 11 may have a gentle curvature.

Here, even when etching time is increased, the etching solution does not penetrate into the panel due to the first etch stop layer ES11 and the second etch stop layer ES12. Thus, the shape of the side surface of the first opening 11 can be freely adjusted by adjusting the etching time.

According to the embodiment, in the structure of forming the first opening, the sharpness of the edge inside the first opening of the substrate 10 can be freely adjusted by adjusting the etching time of the substrate 10.

Referring to FIG. 11E, a side coating layer 31 may be filled in the first opening 11 of the substrate 10. Thereafter, when the side coating layer 31 is cured, the side coating layer 31 is contracted by a predetermined height so that a curvature may be formed on a lower surface 31a of the side coating layer 31.

Thereafter, a back coating layer 32 may be entirely formed on a lower surface of the substrate 10 and the lower surface of the side coating layer 31. However, the present disclosure is not necessarily limited thereto, and the back coating layer 32 may be formed only on the lower surface of the substrate 10.

Referring to FIG. 11F, a light-transmitting area TA may be formed by irradiating a laser to the first opening 11 of the substrate 10. In this case, the first etch stop pattern ES1 and a protruding pattern disposed on the upper portion of the substrate 10 may be removed by the laser. According to the embodiment, a contact area between the protruding pattern and the inorganic insulating layer is increased so that a phenomenon in which the inorganic insulating layer is delaminated during laser irradiation can be improved.

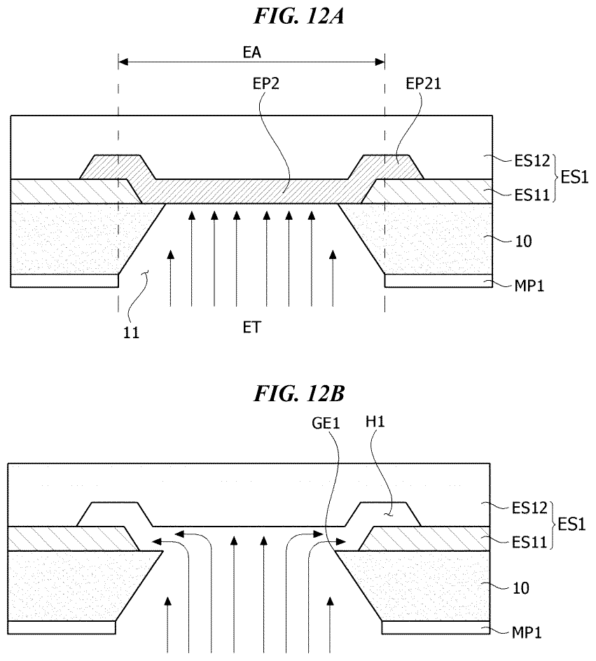

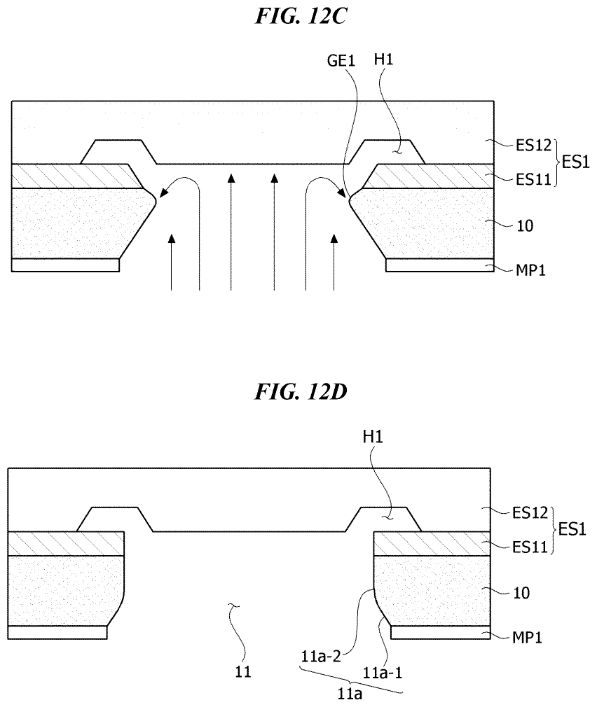

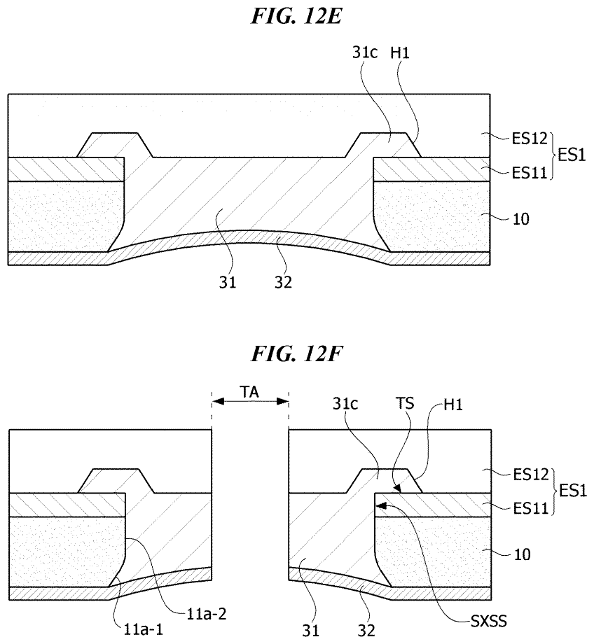

FIGS. 12A to 12F are views illustrating a process of etching a substrate to form a light-transmitting area in a display device according to a second embodiment.

Referring to FIG. 12A, a mask pattern MP1 may be formed on a lower portion of an etch area EA from which a substrate 10 is removed, and a partial area of the substrate 10 may be exposed. A second etching pattern EP2 may be formed on an upper portion of the etch area EA. A first etch stop layer ES11 may be disposed to surround the second etching pattern EP2. A second etch stop layer ES12 may be disposed on the second etching pattern EP2 and the first etch stop layer ES11.

Here, the second etching pattern EP2 may include an extension portion EP21 extending above the first etch stop layer ES11. Since there should be no tolerance between the first etch stop layer ES11 and a second etching pattern EP2 when forming a dummy layer, the second etching pattern EP1 may be formed to partially cover the first etch stop layer ES11 in consideration of the tolerance.

The second etching pattern EP2 may include an inorganic material that is relatively well etched by an etching solution, and the first etch stop layer ES11 and the second etch stop layer ES12 may include a material that is not well etched by the etching solution. As an example, the first etch stop layer ES11 may include an inorganic material such as a-Si or p-Si, or a metal such as molybdenum (Mo). The second etch stop layer ES12 may include an organic material.

When the etching process is performed, the etch area EA of the substrate 10 may be etched from the lower portion thereof. An etching solution may be a hydrofluoric acid solution, but the present disclosure is not necessarily limited thereto. A first opening 11 may be formed in a tapered shape whose diameter becomes smaller toward the upper portion of the etch area EA of the substrate 10.

Referring to FIG. 12B, when the etch area EA of the substrate 10 is etched, the second etching pattern EP2 may be exposed. When the second etching pattern EP2 is etched, an upper surface of the substrate 10 adjacent to the first opening 11 may be gradually exposed. Thus, as the etching process proceeds, an edge GE1 disposed at the upper surface of the substrate 10 may also be etched at the same time as the second etching pattern EP2 is etched.

Here, an upper surface of the first etch stop layer ES11 may be exposed by being etched up to the extension portion EP21 of the second etching pattern EP2. In addition, the extension portion EP21 may be removed to form a first groove H1 between the first etch stop layer ES11 and the second etch stop layer ES12.

Referring to FIG. 12C, the etching process may progress so that the edge GE1 of the second etching pattern EP2, which is disposed at the upper surface of the substrate 10, may be etched. In addition, as the etching process continues, the sharpness of the edge GE1 of the first opening 11 may be mitigated.

Referring to FIG. 12D, a side surface of the first opening 11 of the substrate 10 may be etched to have substantially the same vertical plane as the first etch stop layer ES11. However, the present disclosure is not necessarily limited thereto, and the side surface of the first opening 11 may have various shapes by adjusting etching time.

Referring to FIG. 12E, a side coating layer 31 may be filled in the first opening 11 of the substrate 10. Thereafter, when the side coating layer 31 is cured, the side coating layer 31 is contracted by a predetermined height so that a curvature may be formed on a lower surface of the side coating layer 31. At this time, the side coating layer 31 may include an extension pattern 31c filled even in the first groove H1.

Thereafter, a back coating layer 32 may be entirely formed on a lower surface of the substrate 10 and the lower surface of the side coating layer 31. However, the present disclosure is not necessarily limited thereto, and the back coating layer 32 may be formed only on the lower surface of the substrate 10.

Referring to FIG. 12F, a light-transmitting area TA may be formed by irradiating a laser to the first opening 11 of the substrate 10. In this case, a first etch stop pattern ES1 disposed on the upper portion of the substrate 10 may be removed by the laser.

As shown in FIG. 12F, the first etch stop layer ES11 has a side surface (i.e., sixth side surface SXSS) and a top surface TS. The groove H1 extends into the second etch stop layer ES12 in a location between the first etch stop layer ES11 and the second etch stop layer ES12. The side coating layer 31 is filled in the groove H1. Here, the side coating layer 31 is on and directly contacting the top surface TS and the side surface (i.e., sixth side surface SXSS) of the first etch stop layer ES11.

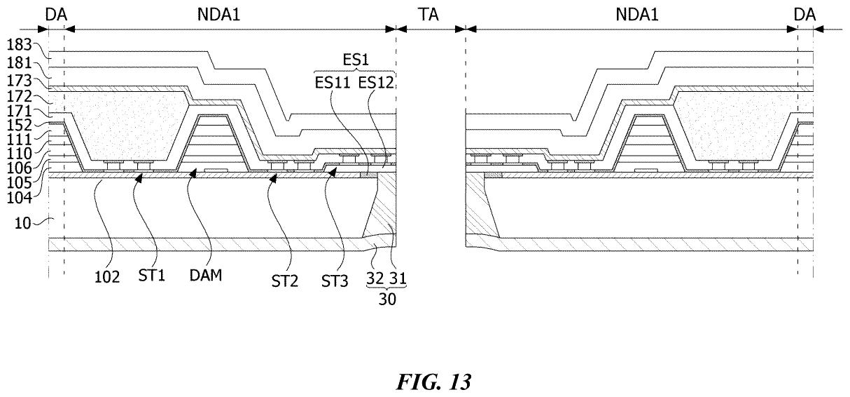

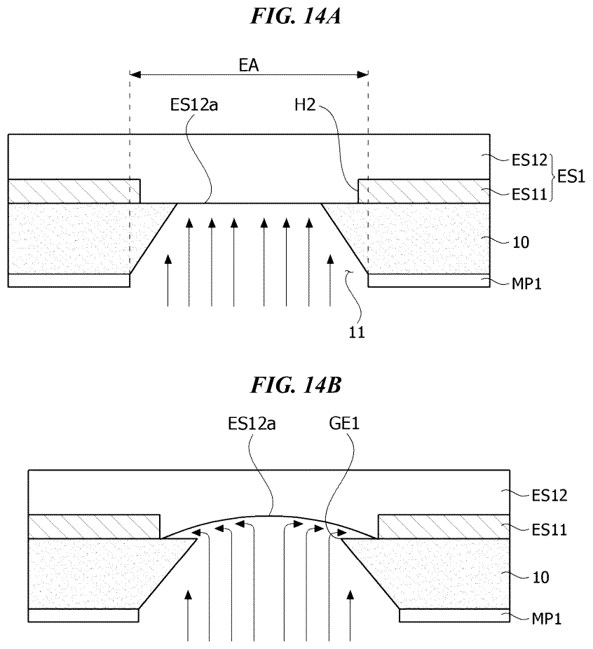

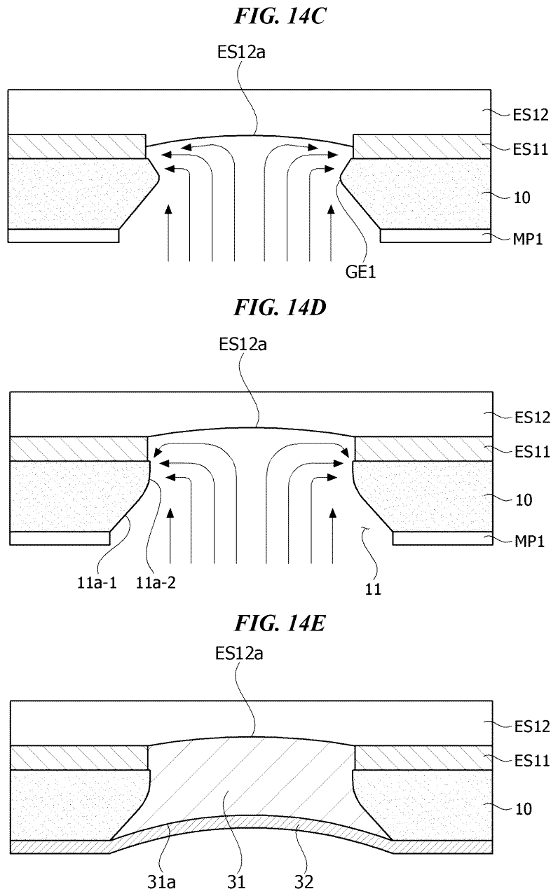

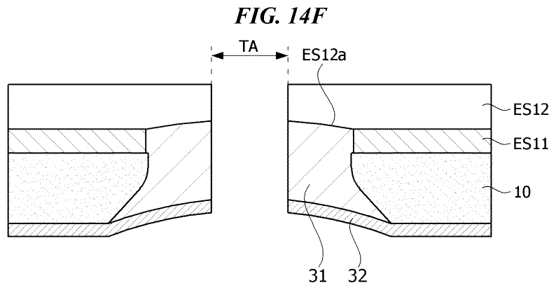

FIG. 13 is a view illustrating a display device according to a third embodiment of the present disclosure. FIGS. 14A to 14F are views illustrating a process of etching a substrate to form a light-transmitting area in the display device according to the third embodiment.

Referring to FIG. 13, dams DAM and a plurality of protruding patterns ST may be formed in a first non-display area NDA1 by using a plurality of layers extending from a display area. The number of dams DAM and protruding patterns ST is not particularly limited.

The dams DAM and the protruding patterns ST may each be disposed in a closed loop shape surrounding a light-transmitting area TA. With this configuration, moisture can be prevented from penetrating into the display area through the light-transmitting area TA.

A first etch stop pattern ES1 may be disposed to surround the light-transmitting area TA. The first etch stop pattern ES1 may include a first etch stop layer ES11 disposed on a substrate 10 and a second etch stop layer ES12 disposed on the first etch stop layer ES11 and protruding toward the light-transmitting area TA than the first etch stop layer ES11.

The first etch stop layer ES11 may include an inorganic material such as a-Si or p-Si, or a metal such as molybdenum. The second etch stop layer ES12 may include an organic material such as polyimide. Thus, the chemical resistance of the second etch stop layer ES12, which is an organic material, to an etching solution such as hydrofluoric acid may be greater. That is, the second etch stop layer ES12 may be less etched by the etching solution than the first etch stop layer ES11.

However, the present disclosure is not necessarily limited thereto, and the first etch stop layer ES11 may include an organic material, and the second etch stop layer ES12 may include an inorganic material such as a-Si or p-Si or a metal such as molybdenum. That is, the first etch stop layer ES11 may be less etched by the etching solution than the second etch stop layer ES12.

Referring to FIG. 14A, a mask pattern MP1 may be formed on a lower portion of a substrate 10 to expose an etch area EA. A first etch stop layer ES11 and a second etch stop layer ES12 may be disposed on the substrate 10. The first etch stop layer ES11 may have a hole H2 formed in an area corresponding to the etch area EA. The second etch stop layer ES12 may include an insertion portion ES12a filled in the hole H2 of the first etch stop layer ES11.

Referring to FIG. 14B, when the etch area EA of the substrate 10 is etched, the insertion portion ES12a of the second etch stop layer ES12 may be exposed to an etching solution. The second etch stop layer ES12 has a strong chemical resistance to the etching solution, but a relatively weak adhesion to the substrate 10. Thus, as the etching proceeds, the adhesion to the substrate 10 may be weakened, causing the insertion portion ES12a of the second etch stop layer ES12 to be separated from the substrate 10. The etching solution may etch an upper surface of the substrate 10 exposed due to the separation of the second etch stop layer ES12.

Referring to FIG. 14C, the second etch stop layer ES12 may be gradually spaced apart from the substrate 10 as etching time elapses. Although the second etch stop layer ES12 may have a relatively strong chemical resistance, a portion of the second etch stop layer ES12 may be physically separated depending on etching conditions. As an example, when the flow rate or hydraulic pressure of the etching solution is increased or the thickness of the second etch stop layer ES12 is small, the second etch stop layer ES12 may be torn off and removed. In addition, depending on the type of an organic material, the second etch stop layer ES12 may be gradually dissolved in the etching solution as the etching time increases.

A curvature may be formed on a lower surface of the insertion portion ES12a. As the etching time increases, the second etch stop layer ES12 is spaced apart from the substrate 10 so that the upper surface of the substrate 10 may be exposed to the etching solution and etched. Thus, the sharpness of an edge GE1 of a first opening 11 of the substrate 10 may be mitigated.

Referring to FIG. 14D, as the etching further proceeds, the first etch stop layer ES11 may be exposed. The first etch stop layer ES11 is less chemically resistant than the second etch stop layer ES12, but may be exposed to the etching solution for a short period of time so that the amount of etching is relatively small.

In the drawing, a side surface of the first etch stop layer ES11 and a side surface 11a of the first opening 11 of the substrate 10 are illustrated as forming a vertical plane, but the present disclosure is not necessarily limited thereto, and the edge GE1 of the substrate 10 may further protrude. In addition, the edge GE1 of the substrate 10 may be a non-planar surface.

Referring to FIG. 14E, a side coating layer 31 may be filled in the first opening 11 of the substrate 10. Thereafter, when the side coating layer 31 is cured, the side coating layer 31 is contracted by a predetermined height so that a curvature may be formed on a lower surface 31a of the side coating layer 31.

Thereafter, a back coating layer 32 may be entirely formed on a lower surface of the substrate 10 and the lower surface of the side coating layer 31. However, the present disclosure is not necessarily limited thereto, and the back coating layer 32 may be formed only on the lower surface of the substrate 10.

Referring to FIG. 14F, a light-transmitting area TA may be formed by irradiating a laser to the first opening 11 of the substrate 10. In this case, a first etch stop pattern ES1 and a protruding pattern disposed on an upper portion of the substrate 10 may be removed by the laser.

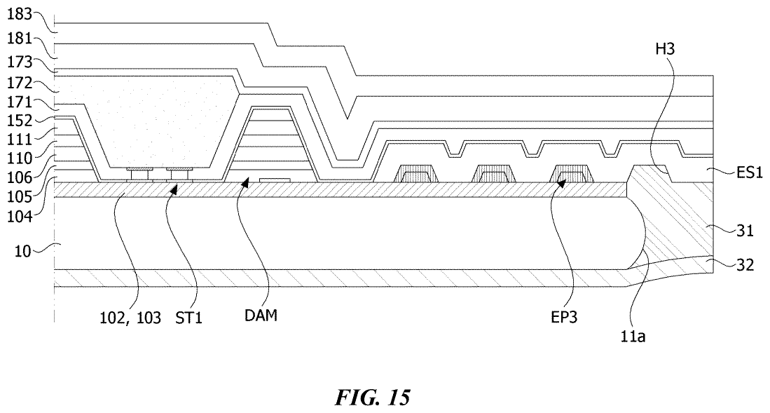

FIG. 15 is a view illustrating a display device according to a fourth embodiment of the present disclosure.

Referring to FIG. 15, an inorganic insulating layer 102 may be disposed on a substrate 10, and a plurality of third etching patterns EP3 may be disposed thereon. The plurality of third etching patterns EP3 may be disposed to be spaced apart from each other and may include an inorganic material that is well etched by an etching solution.

A first etch stop pattern ES1 may be disposed on the plurality of third etching patterns EP3. The first etch stop pattern ES1 may include an organic material or a metal material having a strong chemical resistance to the etching solution.

A third groove H3 may be formed in a partial area of lower surfaces of a plurality of first etch stop patterns ES1, and a side coating layer 31 may be filled in the third groove H3. A side surface 11a of a first opening 11 of the substrate 10 may have a tapered shape or a rounded shape.

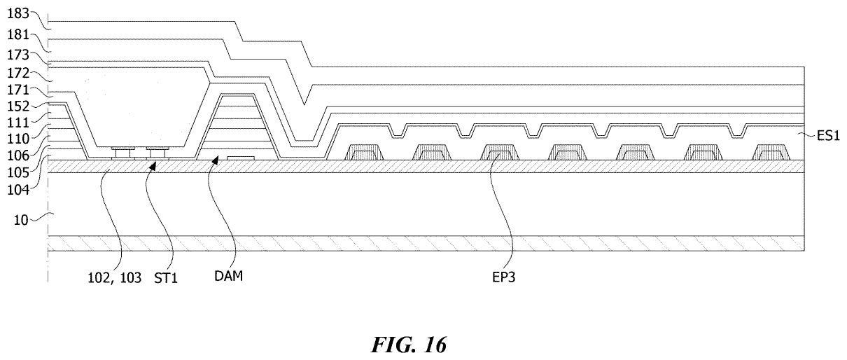

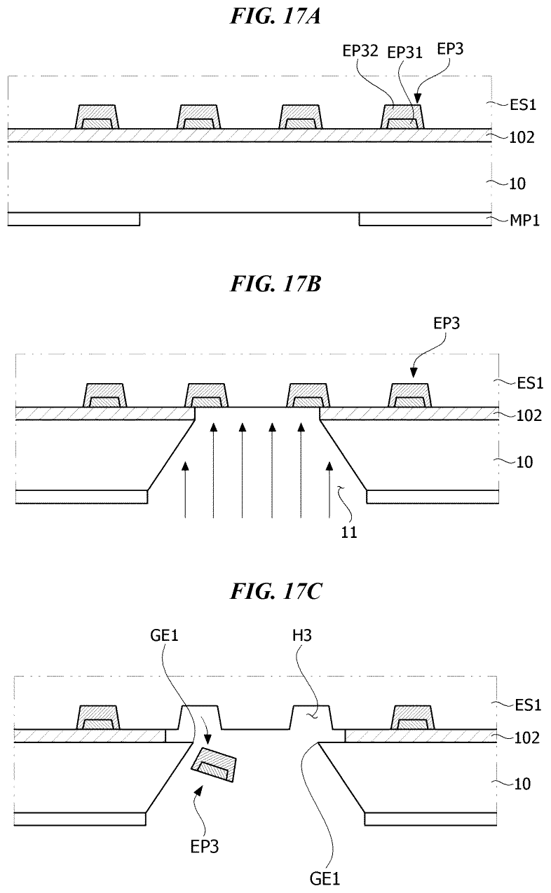

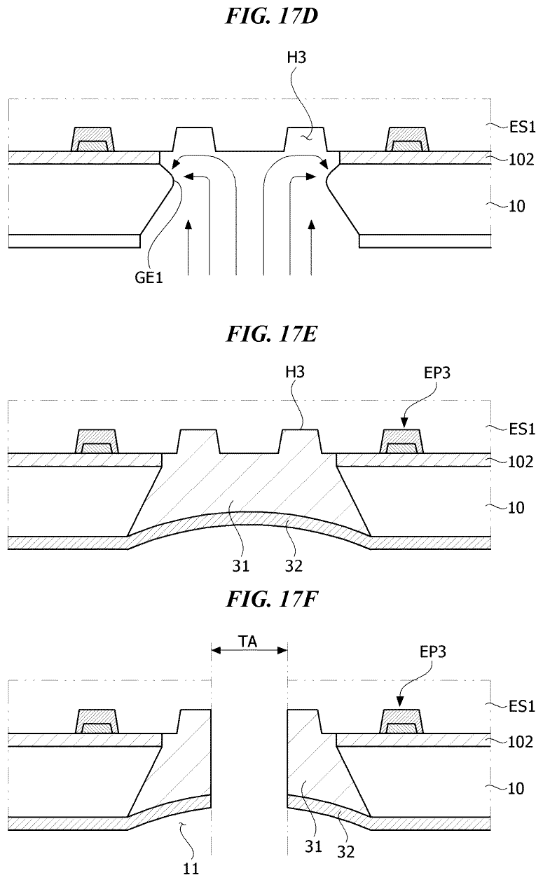

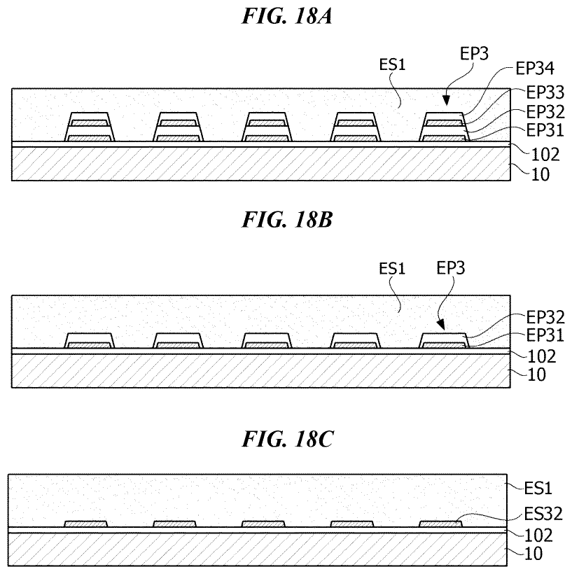

FIG. 16 is a view illustrating the display panel before forming a light-transmitting area. FIGS. 17A to 17F are views illustrating a process of etching a substrate to form the light-transmitting area in the display device according to the fourth embodiment. FIGS. 18A to 18C are views illustrating various forms of etch patterns.

Referring to FIGS. 16 and 17A, a mask pattern MP1 may be formed on a lower surface of a substrate 10 to expose a lower portion of an area from which the substrate 10 is to be etched. An inorganic insulating layer 102 may be disposed on an upper surface of the substrate 10, and a plurality of third etching patterns EP3 may be disposed on the inorganic insulating layer 102.

The plurality of third etching patterns EP3 may each include a metal pattern EP31 and an inorganic pattern EP32 covering the metal pattern EP31. A width of the inorganic pattern EP32 may be made to be greater than a width of the metal pattern EP31.

Referring to FIG. 17B, when a lower portion of the substrate 10 is exposed to an etching solution, an area in which the mask pattern MP1 is not formed is etched. When the substrate 10 of the etching area is removed to form a first opening, the inorganic insulating layer 102 disposed thereon may also be etched. Thus, lower surfaces of the third etching patterns EP3 disposed on the inorganic insulating layer 102 may be exposed to the etching solution.

The metal pattern EP31 of the third etching pattern EP3 has a relatively strong chemical resistance to the etching solution and is not immediately etched, but the inorganic pattern EP32 of the third etching pattern EP3 may be etched by the etching solution relatively quickly.

Referring to FIG. 17C, when the inorganic pattern EP32 of the third etching pattern EP3 is etched, the third etching pattern EP3 may be separated from a first etch stop pattern ES1. Thus, a plurality of third grooves H3 may be formed on a lower surface of the first etch stop pattern ES1. When the third etching pattern EP3 is separated from the first etch stop pattern ES1, the upper surface of the substrate 10 may be exposed.

Referring to FIG. 17D, as the etching solution etches the upper surface of the substrate 10, an edge GE1 of the substrate 10 may gradually become gentle. As etching time increases, a side surface of a first opening 11 of the substrate 10 may be gradually etched.

Referring to FIG. 17E, a side coating layer 31 may be filled in the first opening 11 of the substrate 10. In this case, the side coating layer 31 may be filled in the plurality of third grooves H3 formed on the lower surface of the first etch stop pattern ES1.

Thereafter, a back coating layer 32 may be entirely formed on a lower surface of the substrate 10 and the lower surface of the side coating layer 31. However, the present disclosure is not necessarily limited thereto, and the back coating layer 32 may be formed only on the lower surface of the substrate 10.

Referring to FIG. 17F, a light-transmitting area TA may be formed by irradiating a laser to the first opening 11 of the substrate 10. In this case, the first etch stop pattern ES1 disposed on an upper portion of the substrate 10 may be removed by the laser.

Referring to FIG. 18A, the third etching pattern EP3 may include a first metal pattern EP31, a first inorganic pattern EP32, a second metal pattern EP33, and a second inorganic pattern EP34, which are sequentially stacked. These patterns may be formed as dummy layers when the metal layer and the inorganic insulating layer in the display area are formed.

However, the present disclosure is not necessarily limited thereto, and the shape of the third etching pattern EP3 may be variously modified. As an example, as shown in FIG. 18B, only the metal pattern EP31 and the inorganic pattern EP32 may be formed in the third etching pattern EP3, or, as shown in FIG. 18C, only the metal pattern EP31 may be formed in the third etching pattern EP3. Alternatively, only the inorganic pattern EP32 may be formed. That is, any structure can be applied without limitation, as long as it is separated from the substrate 10 by the etching solution to expose the upper surface of the substrate 10.

Since the content of the present disclosure described in the problems to be solved, the problem-solving means, and effects does not specify essential features of the claims, the scope of the claims is not limited to matters described in the content of the disclosure.

According to the embodiment, there is an advantage in process optimization that allows holes of various shapes to be formed simultaneously in a panel when cutting a mother substrate.

In addition, the sharpness of an edge of a glass substrate can be mitigated so that rigidity can be improved.

In addition, post-processing and component assembly can be facilitated by processing the edge of the glass substrate.

Effects of the present disclosure will not be limited to the above-mentioned effects and other unmentioned effects will be clearly understood by those skilled in the art from the following claims.

While the embodiments of the present disclosure have been described in detail above with reference to the accompanying drawings, the present disclosure is not necessarily limited to these embodiments, and various changes and modifications may be made without departing from the technical spirit of the present disclosure. Accordingly, the embodiments disclosed herein are to be considered descriptive and not restrictive of the technical spirit of the present disclosure, and the scope of the technical spirit of the present disclosure is not limited by these embodiments. Accordingly, the above-described embodiments should be understood to be exemplary and not limiting in any aspect.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area, a light-transmitting area, and a non-display area adjacent to the light-transmitting area;
a circuit portion and a light-emitting element portion disposed in the display area; and
an etch stop pattern disposed in the non-display area,
wherein the substrate includes a first opening disposed at a position corresponding to the light-transmitting area,
wherein the etch stop pattern includes a first etch stop layer adjacent to the first opening and a second etch stop layer disposed on the first etch stop layer, and
wherein the second etch stop layer includes a protrusion extending further toward the light-transmitting area than the first etch stop layer.

2. The display device of claim 1, wherein the first etch stop layer and the second etch stop layer are made of different materials.

3. The display device of claim 1, wherein the first etch stop layer is thinner than the second etch stop layer.

4. The display device of claim 1, wherein a side surface of the first opening protrudes further toward the light-transmitting area than the first etch stop layer.

5. The display device of claim 1, wherein the first opening includes:
a first opening area having a diameter that decreases toward the etch stop pattern;
a second opening area having a diameter that increases toward the etch stop pattern; and
a third opening area disposed between the first opening area and the second opening area,
wherein the diameter of the second opening area is less than the diameter of the first opening area, and
wherein a maximum diameter of the third opening area is less than a maximum diameter of the second opening area.

6. The display device of claim 1, further comprising a third etch stop layer disposed between the first etch stop layer and the second etch stop layer,
wherein the third etch stop layer has a greater chemical resistance to an etching solution than the first etch stop layer.

7. The display device of claim 1, further comprising a plurality of protruding patterns disposed on the etch stop pattern.

8. The display device of claim 7, further comprising:
a plurality of first protruding patterns disposed between the display area and the etch stop pattern; and
a plurality of second protruding patterns disposed on the etch stop pattern.

9. The display device of claim 1, further comprising a side coating layer in the first opening,
wherein the second etch stop layer and the side coating layer include an opening hole formed in an area corresponding to the light-transmitting area,
wherein the second etch stop layer includes a first groove formed in an area overlapping an end portion of the first etch stop layer, and
wherein the side coating layer is in the first groove.

10. The display device of claim 9, further comprising a back coating layer disposed on a lower portion of the substrate and a lower portion of the side coating layer,
wherein the lower portion of the side coating layer has a curvature surface concavely formed toward the etch stop pattern.

11. The display device of claim 1, wherein a lower surface of the protrusion has a curvature.

12. A display device comprising:
a substrate including a display area, a light-transmitting area, and a non-display area adjacent to the light-transmitting area;
a circuit portion and a light-emitting element portion disposed in the display area; and
an etch stop pattern disposed in the non-display area,
wherein the substrate includes a first opening disposed at a position corresponding to the light-transmitting area,
wherein the substrate includes one surface on which the etch stop pattern is disposed and the other surface opposite to the one surface,
wherein the first opening includes a first opening area connected to a lower surface of the substrate and having a diameter decreasing toward the etch stop pattern, and a second opening area connected to an upper surface of the substrate, and
wherein a maximum diameter of the first opening area is greater than a maximum diameter of the second opening area.

13. The display device of claim 12, wherein a side surface of the substrate has the same inclination as the first opening.

14. The display device of claim 12, wherein the etch stop pattern includes a first etch stop layer surrounding the first opening and a second etch stop layer disposed on the first etch stop layer, and
wherein the second etch stop layer includes a protrusion extending further toward the light-transmitting area than the first etch stop layer.

15. The display device of claim 14, wherein the first etch stop layer is thinner than the second etch stop layer, and
wherein a side surface of the first opening protrudes further toward the light-transmitting area than the first etch stop layer.

16. A display device comprising:
a substrate having an opening, the substrate having thereon a display area, a light-transmitting area, and a non-display area, the opening of the substrate overlapping the light-transmitting area from a plan view;
a first etch stop layer on the substrate, the first etch stop layer adjacent to the opening; and
a second etch stop layer on the first etch stop layer, the second etch stop layer having a first protrusion,
wherein the first protrusion of the second etch stop layer does not overlap the first etch stop layer from a plan view.

17. The display device of claim 16, further comprising:
a third etch stop layer between the first etch stop layer and the second etch stop layer, the third etch stop layer including a second protrusion,
wherein the second protrusion of the third etch stop layer does not overlap the first etch stop layer from a plan view, and
wherein the first protrusion of the second etch stop layer extends further towards the opening than the second protrusion of the third etch stop layer.

18. The display device of claim 16, wherein the opening of the substrate defines one or more side surfaces of the substrate,
wherein the one or more side surfaces include a first side surface and a second side surface adjacent to the first side surface at a first side of the opening,
wherein the one or more side surfaces include a third side surface and a fourth side surface adjacent to the third side surface at a second side of the opening that is opposite and facing the first side of the opening,
wherein the first side surface is opposite to and facing the third side surface,
wherein the second side surface is opposite to and facing the fourth side surface,
wherein a first diameter of the opening is defined by a distance between the first side surface and third side surface,
wherein a second diameter is defined by a distance between the second side surface and fourth side surface, and
wherein the first diameter and the second diameter are different from each other.

19. The display device of claim 18, wherein the first etch stop layer includes a fifth side surface and a sixth side surface opposite to and facing the fifth side surface, the sixth side surface of the first etch stop layer located on the other side of the opening of the substrate,
wherein a third diameter is defined by a distance between the fifth side surface and the sixth side surface of the first etch stop layer, and
wherein the third diameter is different from the first and second diameters.

20. The display device of claim 16, further comprising:
a groove between the first etch stop layer and the second etch stop layer; and
a coating layer adjacent to the substrate, the first etch stop layer, and the second etch stop layer,
wherein the groove extends into the second etch stop layer,
wherein the groove at least partially overlaps the substrate from a plan view,
wherein the coating layer includes a side coating layer, and
wherein the side coating layer is extended into the groove.

21. The display device of claim 16, wherein the substrate includes a glass substrate.
